(19) United States
(12) Patent Application Publication
(10) Pub. No.: US 2016/0225859 A1
(43) Pub. Date: Aug. 4, 2016

(54) METAL OXIDE SEMICONDUCTOR FILM, THIN FILM TRANSISTOR, DISPLAY APPARATUS, IMAGE SENSOR, AND X-RAY SENSOR

(71) Applicant: FUJIFILM CORPORATION, Tokyo (JP)

(72) Inventors: Masahiro TAKATA, Kanagawa (JP); Atsushi TANAKA, Kanagawa (JP); Masayuki SUZUKI, Kanagawa (JP)

(21) Appl. No.: 15/095,168

(22) Filed: Apr. 11, 2016

Related U.S. Application Data
(63) Continuation of application No. PCT/JP2014/079769, filed on Nov. 10, 2014.

(30) Foreign Application Priority Data
Dec. 6, 2013 (JP) 2013-253191

(51) Int. Cl. H01L 29/24; H01L 29/786

(52) U.S. Cl. CPC H01L 29/24; H01L 29/7869

(57) ABSTRACT

Provided are a metal oxide semiconductor film and a device including the same, the metal oxide semiconductor film including at least indium as a metal component, in which when an indium concentration in the metal oxide semiconductor film is represented by D_{I} (atoms/cm³), and when a hydrogen concentration in the metal oxide semiconductor film is represented by D_{H} (atoms/cm3), the following relational expression (1) is satisfied:

0.1≦D_{H}/D_{I}≦1.8 (1).

### CROSS-REFERENCE TO RELATED APPLICATIONS

This application is a continuation application of International Application No. PCT/JP2014/079769, filed Nov. 10, 2014, the disclosure of which is incorporated herein by reference in its entirety. Further, this application claims priority from Japanese Patent Application No. 2013-253191, filed Dec. 6, 2013, the disclosure of which is incorporated herein by reference in its entirety.

### BACKGROUND OF THE INVENTION

1. Field of the Invention

The present invention relates to a metal oxide semiconductor film, a thin film transistor, a display apparatus, an image sensor, and an X-ray sensor.

2. Description of the Related Art

The manufacturing of a metal oxide semiconductor film using a vacuum deposition method has been put into practice and is currently attracting attention.

On the other hand, the manufacturing of a metal oxide semiconductor film using a liquid-phase process, which is suitable for forming a metal oxide semiconductor film having strong semiconductor characteristics with a simple method at a low temperature under atmospheric pressure, has been actively researched and developed.

For example, a method of forming a metal oxide semiconductor layer through the coating of a solution including a metal salt such as a nitrate has been disclosed (refer to WO2009/081862A).

In addition, a method of manufacturing a thin film transistor (TFT) having strong transport characteristics at a low temperature of 150° C. or lower has been reported, the method including: coating a substrate with a solution; and irradiating the substrate with ultraviolet rays (refer to Nature, 489 (2012), 128).

In addition, a transistor including an oxide semiconductor film, in which a nitrogen concentration measured by secondary ion mass spectrometry is lower than 5×10¹⁹ atoms/cm³, has been disclosed (refer to JP2013-33934A).

### SUMMARY OF THE INVENTION

An object of the present invention is to provide a dense metal oxide semiconductor film which can be manufactured at a relatively low temperature under atmospheric pressure, a thin film transistor having high mobility, a display apparatus, an image sensor, and an X-ray sensor.

In order to achieve the above-described object, the following configurations are provided.

<1> A metal oxide semiconductor film comprising at least indium as a metal component,
wherein when an indium concentration in the metal oxide semiconductor film is represented by D_{I} (atoms/cm³), and when a hydrogen concentration in the metal oxide semiconductor film is represented by D_{H} (atoms/cm³), the following relational expression (1) is satisfied:

0.1≦D_{H}/D_{I}≦1.8 (1).

<2> The metal oxide semiconductor film according to <1>,
wherein the following relational expression (2) is satisfied:

0.5≦D_{H}/D_{I}≦1.3 (2).

<3> The metal oxide semiconductor film according to <1> or <2>,
wherein an indium content in the metal oxide semiconductor film is 50 atom % or higher with respect to all the metal elements included in the metal oxide thin film.
   <4> The metal oxide semiconductor film according to any one of <1> to <3>,
wherein an average film density is 6 g/cm³ or higher when measured by X-ray reflectometry.
   <5> The metal oxide semiconductor film according to any one of <1> to <4>,
wherein when a nitrogen concentration in the metal oxide semiconductor film is represented by D_{N} (atoms/cm³), the following relational expression (3) is satisfied:

0.004≦D_{N}/D_{I}≦0.012 (3).

<6> The metal oxide semiconductor film according to any one of <1> to <5>,
wherein when a carbon concentration in the metal oxide semiconductor film is represented by D_{C} (atoms/cm³), the following relational expression (4) is satisfied:

0.016≦D_{C}/D_{I}≦0.039 (4).

<7> The metal oxide semiconductor film according to any one of <1> to <6>,
wherein not only indium but also at least one metal element selected from the group consisting of zinc, tin, gallium, and aluminum are included as metal components.

<8> A thin film transistor comprising:
an active layer that includes the metal oxide semiconductor film according to any one of <1> to <7>;
a source electrode;
a drain electrode;
a gate insulating film; and
a gate electrode.
   <9> A display apparatus comprising
the thin film transistor according to <8>.

<10> An image sensor comprising
the thin film transistor according to <8>.

<11> An X-ray sensor comprising
the thin film transistor according to <8>.

According to the present invention, a dense metal oxide semiconductor film which can be manufactured at a relatively low temperature under atmospheric pressure, a thin film transistor having high mobility, a display apparatus, an image sensor, and an X-ray sensor can be provided.

### BRIEF DESCRIPTION OF THE DRAWINGS

FIG. 1 is a schematic diagram showing a configuration example of a thin film transistor (top gate-top contact type) which is manufactured according to the present invention.

FIG. 2 is a schematic diagram showing a configuration example of a thin film transistor (top gate-bottom contact type) which is manufactured according to the present invention.

FIG. 3 is a schematic diagram showing a configuration example of a thin film transistor (bottom gate-top contact type) which is manufactured according to the present invention.

FIG. 4 is a schematic diagram showing a configuration example of a thin film transistor (bottom gate-bottom contact type) which is manufactured according to the present invention.

FIG. 5 is a schematic cross-sectional view showing a part of a liquid crystal display apparatus according to an embodiment of the present invention.

FIG. 6 is a schematic diagram showing a configuration of electric wirings of a liquid crystal display apparatus shown in FIG. 5.

FIG. 7 is a schematic cross-sectional view showing a part of an organic EL display apparatus according to an embodiment of the present invention.

FIG. 8 is a schematic diagram showing a configuration of electric wirings of the organic EL display apparatus shown in FIG. 7.

FIG. 9 is schematic cross-sectional view showing a part of an X-ray sensor array according to an embodiment of the present invention.

FIG. 10 is a schematic diagram showing a configuration of electric wirings of the X-ray sensor array shown in FIG. 9.

FIG. 11 is a diagram showing V_{g}-I_{d} characteristics of each of simple TFTs manufactured in Example 1 and Comparative Example 1.

FIG. 12 is a schematic diagram showing an example of an apparatus for manufacturing a metal oxide semiconductor film according to the present invention.

FIG. 13 is a diagram showing a relationship between D_{H}/D_{I} and TFT mobility in each of metal oxide semiconductor films manufactured in Examples and Comparative Examples.

### DESCRIPTION OF THE PREFERRED EMBODIMENTS

Hereinafter, a metal oxide semiconductor film according to the present invention, and a thin film transistor, a display apparatus, an X-ray sensor, and the like which include the metal oxide semiconductor film will be specifically described with reference to the accompanying drawings.

In the drawings, members (components) having the same or equivalent function are represented by the same reference numeral, and the description thereof will be appropriately omitted. In addition, in this specification, a numerical value range indicated by the expression “to” includes numerical values which are described as a lower limit value and an upper limit value.

In addition, a case where a TFT active layer (semiconductor layer) is used as a representative example of a metal oxide semiconductor film according to the present invention will be mainly described. “Semiconductor film” refers to a film having a medium resistance of 10⁴ Ωm to 10⁴ Ωm.

As a result of detailed study, the present inventors found that an effect of improving a film density and an effect of reducing a hydrogen concentration in the film can be obtained by alternately repeating the following steps multiple times: the formation of a metal oxide precursor film through the coating and drying of a solution including a metal nitrate; and the conversion of the metal oxide precursor film into a metal oxide film through heating.

In particular, by preparing a metal oxide semiconductor film using the method according to the present invention, a thin film transistor having strong transport characteristics can be manufactured at a relatively low temperature under atmospheric pressure. Therefore, a display apparatus such as a thin film liquid crystal display or an organic EL, in particular, a flexible display can be provided.

A metal oxide semiconductor film according to an embodiment of the present invention includes at least indium as a metal component, in which when an indium concentration in the metal oxide semiconductor film is represented by D_{I} (atoms/cm³), and when a hydrogen concentration in the metal oxide semiconductor film is represented by D_{H} (atoms/cm³), the following relational expression (1) is satisfied.

0.1≦D_{H}/D_{I}≦1.8 (1)

Preferably, the following relational expression (2) is satisfied.

0.5≦D_{H}/D_{I}≦1.3 (2)

A method of manufacturing the metal oxide semiconductor film according to the present invention is not particularly limited. First, a method capable of suitably manufacturing the metal oxide semiconductor film according to the present invention will be described.

<Method of Manufacturing Metal Oxide Semiconductor Film>

The metal oxide semiconductor film according to the present invention includes alternately repeating the following steps two or more times, the steps including: a step of coating a substrate with a solution including indium nitrate and drying the coating film to form a metal oxide semiconductor precursor film; and a step of converting the metal oxide semiconductor precursor film into a metal oxide semiconductor film. In at least two times of the steps of converting the metal oxide semiconductor precursor film into a metal oxide semiconductor film, the metal oxide semiconductor precursor film can be converted into a metal oxide semiconductor film by controlling the maximum temperature of the substrate to be 120° C. to 250° C.

The reason why a dense metal oxide semiconductor film can be formed using the method according to the present invention is not clear but is presumed to be as follows.

When the metal oxide semiconductor precursor film is converted into a metal oxide semiconductor film, a nitric acid component or a component coordinated to metal is desorbed from the film. By performing the coating of the solution again in this state, the desorbed portion is impregnated with the solution. As a result, new bonding between the metal and oxygen is formed, thus it is presumed that a dense metal oxide semiconductor film is formed. In addition, it is presumed that hydrogen is likely to be desorbed from the film during the conversion step.

[Step of Forming Metal Oxide Semiconductor Precursor Film (Step A)]

First, a solution including indium nitrate for forming a metal oxide semiconductor film, and a substrate for forming a metal oxide semiconductor film are prepared. Next, the substrate is coated with the solution including indium nitrate, and the coating film is dried to form a metal oxide semiconductor precursor film.

(Substrate)

The shape, structure, size, and the like, of the substrate are not particularly limited and can be appropriately selected according to the purpose. The structure of the substrate may be a single-layer structure or a laminate structure.

A material constituting the substrate is not particularly limited. For example, a substrate formed of an inorganic material such as glass or yttria-stabilized zirconia (YSZ), a resin, or a resin composite material can be used. Among these, a resin substrate or a substrate formed of a resin composite material (resin composite material substrate) is preferable from the viewpoint of being light-weight and flexible.

Specific examples of the substrate include: a fluororesin such as polybutylene terephthalate, polyethylene terephthalate, polyethylene naphthalate, polybutylene naphthalate, polystyrene, polycarbonate, polysulfone, polyethersulfone, polyarylate, allyl diglycol carbonate, polyamide, polyimide, polyamide imide, polyether imide, polybenzazole, polyphenylene sulfide, polycycloolefin, a norbornene resin, or polychlorotrifluoroethylene; and a synthetic resin substrate such as a liquid crystal polymer, an acrylic resin, an epoxy resin, a silicone resin, an ionomer resin, a cyanate resin, a cross-linked fumaric acid diester, a cyclic polyolefin, an aromatic ether, maleimide-olefin, cellulose, or an episulfide compound.

In addition, examples of an inorganic material included in the composite material of the inorganic material and a resin include: inorganic particles such as silicon oxide particles, metal nanoparticles, inorganic oxide nanoparticles, or inorganic nitride nanoparticles; a carbon material such as carbon fiber or carbon nanotube; and a glass material such as glass flake, glass fiber, or glass beads.

Other examples of the composite material include: a composite plastic material including a resin and clay mineral; a composite plastic material including a resin and particles having a mica-derived crystal structure; a laminated plastic material having at least one bonded interface between a resin and thin glass; and a composite material with barrier performance having at least one bonded interface which is obtained by alternately laminating an inorganic layer and an organic layer.

In addition, for example, a stainless steel substrate or a multilayer metal substrate obtained by laminating stainless steel and another different metal; or an aluminum substrate or an aluminum substrate with an oxide film in which an oxidation treatment (for example, anodic oxidation) is performed on a surface thereof to improve insulating characteristics of the surface can also be used.

Moreover, it is preferable that the resin substrate or the resin composite material substrate is superior in heat resistance, dimension stability, solvent resistance, electric insulating characteristics, workability, low gas permeability, low hygroscopicity, and the like. The resin substrate or the resin composite material substrate may include, for example, a gas barrier layer for preventing permeation of water, oxygen, or the like, or an undercoat layer for improving flatness of the substrate or adhesiveness with a lower electrode.

The thickness of the substrate used in the present invention is not particularly limited and is preferably 50 μm to 500 μm. When the thickness of the substrate is 50 μm or more, the flatness of the substrate is further improved. In addition, when the thickness of the substrate is 500 μm or less, the flexibility of the substrate is further improved and can be more easily used as a substrate for a flexible device.

(Solution Including Indium Nitrate)

The solution including indium nitrate is obtained by weighing indium nitrate such that the solution has a desired concentration, and dissolve indium nitrate in a solvent under stirring. The stirring time is not particularly limited as long as the solute is sufficiently dissolved in the solvent.

The metal molar concentration in the solution can be appropriately selected according to the viscosity or the desired film thickness, but is preferably 0.01 mol/L to 0.5 mol/L from the viewpoint of the flatness of the film and productivity. When the metal molar concentration in the solution is 0.01 mol/L or higher, the film density can be efficiently improved. In addition, in a case where the solution is applied to the metal oxide semiconductor film to form a metal oxide semiconductor precursor film, it is preferable that the metal molar concentration in the solution is 0.5 mol/L or lower from the viewpoint of efficiently suppressing the dissolution of the metal oxide semiconductor film which is positioned below the metal oxide semiconductor precursor film.

In a case where the solution including indium nitrate includes a metal other than indium, the metal molar concentration described in the present invention refers to the sum of the molar concentrations (mol/L) of the respective metals.

The solution including indium nitrate may include an indium salt other than indium nitrate, or another metal atom-containing compound. Examples of the metal atom-containing compound include a metal salt other than a metal nitrate, a metal halide, and an organic metal compound.

Examples of the metal salt other than a metal nitrate include a sulfate, a phosphate, a carbonate, an acetate, and an oxalate. Examples of the metal halide include a chloride, an iodide, and a bromide. Examples of the organic metal compound include a metal alkoxide, an organic acid salt, and a metal β diketonate.

The indium content in the solution including indium nitrate is preferably 50 atom % or higher with respect to all the metal elements included in the metal oxide thin film. By using this solution, a metal oxide semiconductor film having high electrical conductivity can be easily obtained.

In addition, in a case where the step of converting the metal oxide semiconductor precursor film into a metal oxide semiconductor film includes a step of irradiating the metal oxide semiconductor precursor film with ultraviolet rays, the precursor film can efficiently absorb ultraviolet rays, and thus an indium-containing oxide semiconductor film can be easily formed.

In addition, it is preferable that the solution including indium nitrate includes a compound including one or more kinds of metal atoms selected from zinc, tin, gallium, and aluminum as metal element other than indium. By the solution including not only indium but also an appropriate amount of the metal element other than indium, a threshold voltage of the obtained metal oxide semiconductor film can be controlled to be a desired value, and the electrical stability of the film can be improved.

Examples of the oxide semiconductor film including indium and the metal element other than indium include In—Ga—Zn—O (IGZO), In—Zn—O (IZO), In—Ga—O (IGO), In—Sn—O (ITO), and In—Sn—Zn—O (ITZO).

A solvent used in the solution including indium nitrate is not particularly limited as long as indium nitrate and the metal atom-containing compound can be dissolved therein, and examples thereof include water, an alcohol solvent (for example, methanol, ethanol, propanol, or ethylene glycol), an amide solvent (for example, N,N-dimethylformamide), a ketone solvent (for example, acetone, N-methylpyrrolidone, sulfolane, N,N-dimethylimidazolidinone), an ether solvent (for example, tetrahydrofuran or methoxyethanol), a nitrile solvent (for example, acetonitrile), and a solvent containing a heteroatom other than the above-described solvents. From the viewpoints of solubility and wettability, for example, methanol or methoxyethanol is particularly preferably used.

(Coating)

A method of coating the substrate with the solution including indium nitrate (coating solution for forming a metal oxide semiconductor film) is not particularly limited, and examples thereof include a spray coating method, a spin coating method, a blade coating method, a dip coating method, a cast method, a roll coating method, a bar coating method, a die coating method, a mist method, an ink jet method, a dispenser method, a screen printing method, a relief printing method, and an intaglio printing method. In particular, from the viewpoint of easily forming a fine pattern, it is preferable that at least one coating method selected from the group consisting of an ink jet method, a dispenser method, a relief printing method, and an intaglio printing method is used.

(Drying)

The substrate is coated with the coating solution for forming a metal oxide semiconductor film, and the coating film is dried. As a result, a first metal oxide semiconductor precursor film is obtained. Due to the drying, the fluidity of the coating film can be reduced, the flatness of the finally obtained oxide semiconductor film can be improved.

By selecting an appropriate drying temperature (for example, the temperature of the substrate is 35° C. to 100° C.), finally, a more dense metal oxide semiconductor film can be obtained. A heating method for drying is not particularly limited and, for example, can be selected from hot plate heating, electric furnace heating, infrared heating, and microwave heating.

From the viewpoint of uniformly maintaining the flatness of the film, it is preferable that the drying is started within 5 minutes after the coating.

The drying time is not particularly limited but is preferably 15 seconds to 10 minutes from the viewpoints of the uniformity of the film and productivity.

In addition, the atmosphere during the drying is not particularly limited. However, from the viewpoint of manufacturing costs and the like, it is preferable that the drying is performed in air under atmospheric pressure.

[Conversion Step into Metal Oxide Semiconductor Film (Step B)]

Next, the metal oxide semiconductor precursor film obtained by the drying is converted into a metal oxide semiconductor film. A method of converting the metal oxide semiconductor precursor film into a metal oxide semiconductor film is not particularly limited as long as the maximum temperature of the substrate can be controlled to be 120° C. to 250° C., and examples thereof include a method using a heater such as a hot plate, an electric furnace, plasma, ultraviolet rays, microwaves, or the like.

When the maximum temperature of the substrate in the conversion step is lower than 120° C., the effect of improving the film density is insufficient. When the maximum temperature of the substrate in the conversion step is higher than 250° C., the process costs increase.

From the viewpoint of converting the metal oxide semiconductor precursor film into a metal oxide semiconductor film at a lower temperature, a method using ultraviolet (UV) rays is preferable. Examples of a light source of the ultraviolet rays include a UV lamp and a laser. An UV lamp is preferable from the viewpoints of uniformly irradiating a large area with ultrasonic rays with inexpensive facilities.

Examples of the UV lamp include an excimer lamp, a deuterium lamp, a low pressure mercury lamp, a high pressure mercury lamp, an extra high pressure mercury lamp, a metal halide lamp, an helium lamp, a carbon arc lamp, a cadmium lamp, and an electrodeless discharge lamp. In particular, it is preferable that a low pressure mercury lamp is used because the conversion of the metal oxide semiconductor precursor film into a metal oxide semiconductor film can be easily performed.

In the conversion step, it is preferable that the surface of the metal oxide semiconductor precursor film is irradiated with ultraviolet rays having a wavelength of 300 nm or shorter at an illuminance of 10 mW/cm² or higher. By irradiating the surface with the ultraviolet rays in the above-described wavelength range and in the above-described illuminance range, the conversion of the metal oxide semiconductor precursor film into a metal oxide semiconductor film can be performed within a short period of time.

The illuminance at which the metal oxide semiconductor precursor film is irradiated with ultraviolet rays can be measured, for example, using an ultraviolet light meter (UV-M10, manufactured by Orc Manufacturing Co., Ltd., optical receiver UV-25).

The atmosphere in the conversion step is not limited, and the conversion may be performed in air or in an arbitrary gas under atmospheric pressure or in a vacuum. From the viewpoint of easily performing the conversion, it is preferable that the conversion is performed under atmospheric pressure.

In the conversion step, the maximum temperature of the substrate is preferably 200° C. or lower. When the maximum temperature of the substrate is 200° C. or lower, the application to a resin substrate having low heat resistance is easy. The maximum temperature of the substrate in the conversion step can be measured, for example, using THERMO LABEL or a thermocouple-embedded wafer.

A method of controlling the temperature of the substrate is not particularly limited as long as it can control the temperature of the substrate to be in the above-described temperature range. For example, the substrate temperature may be controlled using a heater such as a hot plate, an electric furnace, or microwave heating, or may be controlled using radiation heat from a light source such as an ultraviolet lamp. When radiation heat from a light source is used, the substrate temperature can be controlled by adjusting the distance between the lamp and the substrate or a lamp output.

Although depending on the illuminance of ultraviolet rays, the ultraviolet irradiation time is 5 seconds to 120 minutes from the viewpoint of productivity.

[Repeating of Step A and Step B]

After the metal oxide semiconductor precursor film is converted into a metal oxide semiconductor film, the metal oxide semiconductor film is coated again with the solution including indium nitrate, the coating film is dried to form a metal oxide semiconductor precursor film, and the metal oxide semiconductor precursor film is converted into a metal oxide semiconductor film. As a result, the additional metal oxide semiconductor film is formed on the metal oxide semiconductor film.

In this way, the step of forming a metal oxide semiconductor precursor film (Step A) and the step of converting the metal oxide semiconductor precursor film into a metal oxide semiconductor film (Step B) are alternately repeated two or more times, thereby forming metal oxide semiconductor films repeatedly and integrally. As a result, a metal oxide semiconductor film having a high film density and a low hydrogen concentration can be obtained.

Regarding Step A and Step B, there is no particular limitation as long as the performing order of Step A and Step B is A→B→A→B. For example, it is not necessary to continuously perform Step A and Step B, and another step such as a step of forming an electrode or an insulating film may be performed between Step A and Step B.

In addition, in a case where the step of forming a metal oxide semiconductor precursor film and the step of converting the metal oxide semiconductor precursor film into a metal oxide semiconductor film are alternately repeated N times (N represents an integer of 2 or more), it is not necessary that the maximum temperature of the substrate is 120° C. to 250° C. at all times in N times of the conversion steps of converting the metal oxide semiconductor precursor film into a metal oxide semiconductor film. The metal oxide semiconductor precursor film may be converted into a metal oxide semiconductor film by controlling the maximum temperature of the substrate to be 120° C. to 250° C. in at least two continuous times of the conversion steps among N times of the conversion steps, that is, in the n-th and (n+1)-th conversion steps ((n represents an integer of 1 to (N−1)). For example, in a case where the formation of a metal oxide semiconductor precursor film and the conversion of the metal oxide semiconductor precursor film into a metal oxide semiconductor film are repeated three times, the maximum temperature of the substrate may be set to be 120° C. to 250° C. in the first and second conversion steps and to be lower than 120° C. in the third conversion step. Alternatively, the maximum temperature of the substrate may be set to be lower than 120° C. in the first conversion step and to be 120° C. to 250° C. in the second and third conversion steps.

However, it is preferable that the metal oxide semiconductor precursor film is converted into a metal oxide semiconductor film by controlling the maximum temperature of the substrate to be 120° C. to 250° C. in all the steps of converting the metal oxide semiconductor precursor film into a metal oxide semiconductor film.

It is preferable that Step A and Step B are repeated on the same substrate four or more times. By alternately repeating Step A and Step B four or more times (repeating a set of Step A and Step B four or more times), a high-quality metal oxide semiconductor film having a higher film density and a lower hydrogen concentration can be obtained.

The number of times of Step A and Step B repeated is not particularly limited as long as it is 2 or more, and may be determined in consideration of the desired thickness of the metal oxide semiconductor film and the like. From the viewpoint of productivity, the number of times of Step A and Step B repeated is preferably 10 or less.

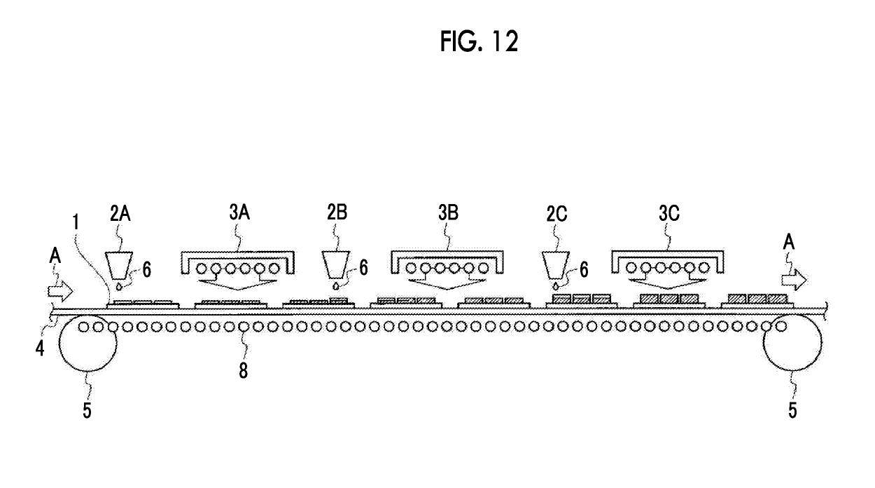

As a manufacturing form for forming a metal oxide semiconductor film by alternately repeating Step A and Step B two or more times, for example, the following form is preferable. FIG. 12 schematically shows an example of an apparatus for manufacturing a metal oxide semiconductor film according to the present invention. This apparatus has a configuration in which a metal oxide semiconductor film is formed using a roll-to-roll method. This apparatus includes: coating units 2 (2A, 2B, 2C) using an ink jet method or the like and converting units 3 (3A, 3B, 3C) using ultraviolet irradiation that are alternately continuously arranged; a transport belt 4 and transport rolls 5 through which substrates 1 are transported; and temperature control means 8 for controlling the temperature of the substrate 1. The substrates 1 that are arranged on the transport belt 4 at predetermined intervals move in a direction indicated by arrow A along with the transport belt 4 due to the rotation of the transport roll 5, and a solution 6 including indium nitrate is applied to each of the substrates 1 in the coating unit 2A. As a result, a metal oxide semiconductor precursor film is formed. Next, in the converting unit 3A, the substrate 1 is irradiated with ultraviolet rays, and the substrate 1 is heated by the temperature control means 8 such that the maximum temperature of the substrate 1 is in a range of 120° C. to 250° C. As a result, the metal oxide semiconductor precursor film is converted into a metal oxide semiconductor film. Similarly, the formation of a metal oxide semiconductor precursor film and the conversion of the metal oxide semiconductor precursor film into a metal oxide semiconductor film are repeatedly performed by the second coating unit 2B and the second converting unit 3B and by the third coating unit 2C and the third converting unit 3C. In this way, Step A and Step B can be efficiently repeated within a short period of time.

The average thickness of the metal oxide semiconductor film which is obtained by repeating Step A and Step B once is preferably 6 nm or less and more preferably 2 nm or less. By controlling the average thickness of the metal oxide semiconductor film, which is obtained by repeating Step A and Step B once, to be 6 nm or less, finally, a metal oxide semiconductor film having a high film density and a low hydrogen concentration can be obtained. When the average thickness is 2 nm or less, the effect can be further improved. The average thickness described herein refers to a value obtained by dividing the thickness of a metal oxide semiconductor film, which is manufactured by alternately repeating Step A and Step B multiple times, by the number of times of coating (the number of times of Step A). For example, in a case where the thickness of a metal oxide semiconductor film, which is finally obtained by alternately repeating Step A and Step B two times, is 10 nm, the average thickness is 10/2=5 nm. The thickness of the finally obtained metal oxide semiconductor film can be evaluated by observing a section of the film with a transmission electron microscope (TEM).

<Metal Oxide Semiconductor Film>

The above-described metal oxide semiconductor film which is manufactured by alternately repeating Step A and Step B multiple times has an extremely low hydrogen concentration. The concentration of impurities such as hydrogen in the film is a value measured by secondary ion mass spectrometry (SIMS). It is known that, with the SIMS analysis, due to the principle thereof, it is difficult to obtain accurate data in the vicinity of a sample surface or in the vicinity of an interface between different materials. In a case where an impurity concentration distribution in a thickness direction of the film is analyzed, there is no extreme variation in strength in a range where the metal oxide semiconductor film is present, and a value of a region where the strength is substantially uniform is adopted.

The metal oxide semiconductor film according to the present invention includes at least indium as a metal component, in which when an indium concentration in the metal oxide semiconductor film is represented by D_{I} (atoms/cm³), and when a hydrogen concentration in the metal oxide semiconductor film is represented by D_{H} (atoms/cm³), the following relational expression (1) is satisfied.

0.1≦D_{H}/D_{I}≦1.8 (1)

The dense metal oxide semiconductor film, which is manufactured through the above-described steps, satisfies the above-described relational expression (1), can be obtained at a low temperature, and exhibits high electrical conductivity.

It is preferable that the metal oxide semiconductor film according to the present invention satisfies the following relational expression (2).

0.5≦D_{H}/D_{I}≦1.3 (2)

By satisfying the relational expression (2), a metal oxide semiconductor film having high electrical conductivity can be more stably obtained.

It is preferable that the indium content in the metal oxide semiconductor film is 50 atom % or higher with respect to all the metal elements included in the metal oxide thin film. When the indium content in the metal oxide semiconductor film according to the present invention is 50 atom % or higher, high electrical conductivity can be easily obtained at a low temperature.

It is preferable that the average film density of the metal oxide semiconductor film according to the present invention is 6 g/cm³ or higher when measured by X-ray reflectometry. When the average film density is in the above-described range, a metal oxide semiconductor film having high electrical conductivity can be obtained. When the metal oxide semiconductor film is set as a model for plural layers having different densities by using a film thickness, a film density, and a surface roughness, which are obtained from the XRR spectrum, as fitting parameters, the average film density described herein refers to a value obtained by multiplying the densities of the respective layers by the thicknesses thereof, respectively, adding up the obtained values, and dividing the added value by the total thickness of the metal oxide semiconductor film. For example, in a case where the metal oxide semiconductor film has a three-layer structure, it is assumed that the actual spectrum of the metal oxide semiconductor film show good agreement with the simulation results, the first layer has a density of 4 g/cm³ and a thickness of 1 nm, the second layer has a density of 5 g/cm³ and a thickness of 8 nm, and the third layer has a density of 4 g/cm³ and a thickness of 1 nm. In this case, the average film density of the metal oxide semiconductor film is (4×1+5×8+4×1)/(1+8+1)=4.8 g/cm³. Whether or not the actual spectrum shows good agreement with the simulation result can be estimated from a reliability factor (R value). The good agreement represents that the R value is 0.015 or less.

When the nitrogen concentration in the metal oxide semiconductor film according to the present invention is represented by D_{N} (atoms/cm³), it is preferable that the following relational expression (3) is satisfied.

0.004≦D_{N}/D_{I}≦0.012 (3)

By satisfying the relational expression (3), a metal oxide semiconductor film having high electrical conductivity can be obtained. By including a metal oxide semiconductor film, which satisfies not only the relational expression (1) but also the relational expression (3), as an active layer, a thin film transistor having improved driving stability can be obtained.

When the carbon concentration in the metal oxide semiconductor film according to the present invention is represented by D_{C} (atoms/cm³), it is preferable that the following relational expression (4) is satisfied.

0.016≦D_{C}/D_{I}≦0.039 (4)

By satisfying the relational expression (4), a metal oxide semiconductor film having high electrical conductivity can be obtained. By including a metal oxide semiconductor film, which satisfies not only the relational expression (1) but also the relational expression (4), as an active layer, a thin film transistor having improved driving stability can be obtained.

In the metal oxide semiconductor film according to the present invention, it is preferable that at least one metal element selected from the group consisting of zinc, tin, gallium, and aluminum is included as a metal component other than indium. Since the metal oxide semiconductor film according to the present invention includes not only indium but also an appropriate amount of the metal element other than indium, an effect of improving electrical conductivity, an effect of controlling a threshold voltage, or an effect of improving electrical stability can be obtained. Examples of the oxide semiconductor film including indium and the metal element other than indium include In—Ga—Zn—O (IGZO), In—Zn—O (IZO), In—Ga—O (IGO), In—Sn—O (ITO), and In—Sn—Zn—O (ITZO).

By using the above-described method of manufacturing a metal oxide semiconductor film, for example, a dense metal oxide semiconductor film can be obtained through a low-temperature process of 200° C. or lower under atmospheric pressure and is applicable to the preparation of various devices. The metal oxide semiconductor film according to the present invention can be manufactured at a low temperature without using a large-sized vacuum device. Therefore, the metal oxide semiconductor film can be formed on an inexpensive resin substrate having low heat resistance, and the costs of manufacturing a device can be significantly reduced.

In addition, since the metal oxide semiconductor film according to the present invention is applicable to a resin substrate having low heat resistance, a flexible electronic device such as a flexible display can be manufactured at a low cost.

<Thin Film Transistor>

The metal oxide semiconductor film according to the present invention has strong semiconductor characteristics and thus can be suitably used as a thin film transistor (TFT) active layer (oxide semiconductor layer). Hereinafter, an embodiment in which the metal oxide semiconductor film according to the present invention is used as an active layer of a thin film transistor will be described.

In the following embodiment, a top gate type thin film transistor will be described in detail. However, the thin film transistor in which metal oxide semiconductor film according to the present invention is used is not limited to the top gate type and may be a bottom gate type thin film transistor.

A device structure of the TFT according to the present invention is not particularly limited and, based on the position of a gate electrode, may be any one of a so-called inverted staggered structure (also referred to as “bottom gate type) and a staggered structure (also referred to as “top gate type”). In addition, based on a contact portion between an active layer and source and drain electrodes (also appropriately referred to as “source-drain electrodes”), the device structure of a TFT may be any one of a so-called top contact type and a bottom contact type.

When a substrate on which a TFT is formed is the bottom layer, the top gate type refers to a configuration in which a gate electrode is arranged above a gate insulating film and in which an active layer is formed below the gate insulating film. The bottom gate type refers to a configuration in which a gate electrode is arranged below a gate insulating film and in which an active layer is formed above the gate insulating film. In addition, the bottom contact type refers to a configuration in which source-drain electrodes are formed before an active layer and in which a lower surface of the active layer contacts the source-drain electrodes. The top contact type refers to a configuration in which an active layer are formed before source-drain electrodes and in which an upper surface of the active layer contacts the source-drain electrodes.

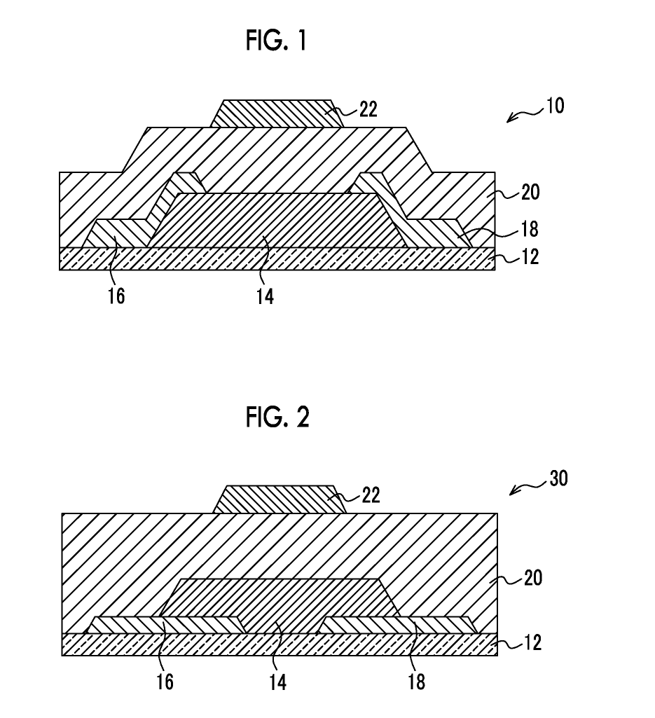

FIG. 1 is a schematic diagram showing an example of a top contact type TFT according to the present invention having a top gate structure. In a TFT 10 shown in FIG. 1, the above-described metal oxide semiconductor film is laminated on one main surface of a substrate 12 as an active layer 14. A source electrode 16 and a drain electrode 18 are provided on the active layer 14 to be separated from each other. Further, a gate insulating film 20 and a gate electrode 22 are laminated in this order on the source electrode 16 and the drain electrode 18.

FIG. 2 is a schematic diagram showing an example of a bottom contact type TFT according to the present invention having a top gate structure. In a TFT 30 shown in FIG. 2, the source electrode 16 and the drain electrode 18 are provided on one main surface of the substrate 12 to be separated from each other. Next, the above-described metal oxide semiconductor film as the active layer 14, the gate insulating film 20, and the gate electrode 22 are laminated in this order.

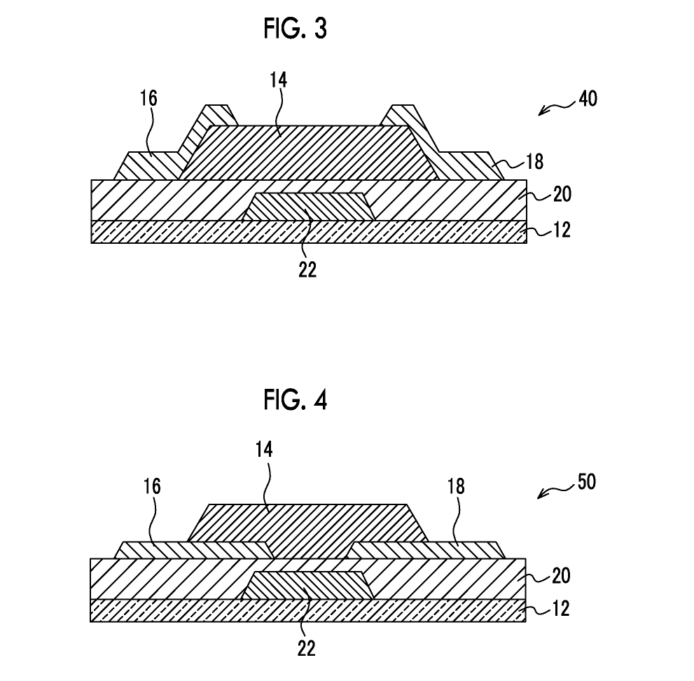

FIG. 3 is a schematic diagram showing an example of a top contact type TFT according to the present invention having a bottom gate structure. In a TFT 40 shown in FIG. 3, the gate electrode 22, the gate insulating film 20, and the above-described metal oxide semiconductor film as the active layer 14 are laminated in this order on one main surface of the substrate 12. The source electrode 16 and the drain electrode 18 are provided on a surface of the active layer 14 to be separated from each other.

FIG. 4 is a schematic diagram showing an example of a bottom contact type TFT according to the present invention having a bottom gate structure. In a TFT 50 shown in FIG. 4, the gate electrode 22 and the gate insulating film 20 are laminated in this order on one main surface of the substrate 12. The source electrode 16 and the drain electrode 18 are provided on a surface of the gate insulating film 20 to be separated from each other. Further, the above-described metal oxide semiconductor film as the active layer 14 is laminated on the source electrode 16 and the drain electrode 18.

In the following embodiment, the top gate type thin film transistor 10 shown in FIG. 1 will be mainly described. However, the thin film transistor according to the present invention is not limited to the top gate type and may be a bottom gate type thin film transistor.

(Active Layer)

In a case where the thin film transistor 10 according to the embodiment is manufactured, first, a solution including indium nitrate is prepared. Next, a step of forming a metal oxide semiconductor precursor film and a step of converting the metal oxide semiconductor precursor film into a metal oxide semiconductor film are alternately repeated two or more times. As a result, a metal oxide semiconductor film is formed on the substrate 12.

In addition, the metal oxide semiconductor film may be patterned using the above-described method such as an ink jet method, a dispenser method, a relief printing method, or an intaglio printing method, or may be patterned after the formation of the metal oxide semiconductor film using photolithography and etching.

In order to form a pattern of the active layer 14 using photolithography and etching, after the formation of the metal oxide semiconductor film, a resist pattern is formed on a remaining portion for forming the active layer 14 using photolithography and then is etched using an acid solution such as hydrochloric acid, nitric acid, dilute sulfuric acid, or a mixed liquid of phosphoric acid, nitric acid, and acetic acid.

From the viewpoint of securing the flatness of the film and the time required to form the film, the thickness of the metal oxide semiconductor film is preferably 5 nm to 50 nm.

In addition, from the viewpoint of obtaining high mobility, the content of indium in the active layer 14 is preferably 50 atom % or higher and more preferably 80 atom % or higher with respect to all the metal elements included in the active layer 14.

(Protective Layer)

It is preferable that a protective layer (not shown) is formed on the active layer 14 to protect the active layer 14 during the etching of the source-drain electrodes 16 and 18. A method of forming the protective layer is not particularly limited. For example, after the formation of the metal oxide semiconductor film, the protective layer may be formed before or after the patterning of the metal oxide semiconductor film.

In addition, the protective layer may be formed of a metal oxide semiconductor layer or an organic material such as a resin. The protective layer may be removed after the formation of the source electrode 16 and the drain electrode 18 (appropriately referred to as “source-drain electrodes”).

(Source-Drain Electrodes)

The source-drain electrodes 16 and 18 are formed on the active layer 14 which is formed of the metal oxide semiconductor film. The source-drain electrodes 16 and 18 can be formed of a highly conductive material so as to function as electrodes, respectively, and examples of the material include metal such as Al, Mo, Cr, Ta, Ti, Au, or Au, Al—Nd, a Ag alloy, and a metal oxide conductive film such as tin oxide, zinc oxide, indium oxide, indium tin oxide (ITO), indium zinc oxide (IZO) or In—Ga—Zn—O.

The source-drain electrodes 16 and 18 may be formed using a method which is appropriately selected from a wet method such as a printing method or a coating method, a physical method such as a vacuum deposition method, a sputtering method, or an ion plating method, and a chemical method such as a CVD method or a plasma CVD method in consideration of aptitude with a material to be used.

In consideration of film formability, patterning characteristics using an etching or lift-off method, conductivity, and the like, the thickness of the source-drain electrodes 16 and 18 is preferably 10 nm to 1000 nm and more preferably 50 nm to 100 nm.

The source-drain electrodes 16 and 18 may be formed, for example, by forming a conductive film and then patterning the conductive film into a predetermined shape using an etching or lift-off method or by directly forming a pattern using an ink jet method or the like. At this time, it is preferable that the source-drain electrodes 16 and 18 and wirings (not shown) for connection to these electrodes are simultaneously patterned.

(Gate Insulating Film)

After the formation of the source-drain electrodes 16 and 18 and the wirings (not shown), the gate insulating film 20 is formed. It is preferable that the gate insulating film 20 has high insulating characteristics and may be, for example, an insulating film such as SiO₂, SiNₓ, SiON, Al₂O₃, Y₂O₃, Ta₂O₅, or HfO₂ or an insulating film including two or more of the above compounds.

The gate insulating film 20 may be formed using a method which is appropriately selected from a wet method such as a printing method or coating method, a physical method such as a vacuum deposition method, a sputtering method, or an ion plating method, and a chemical method such as a CVD method or a plasma CVD method in consideration of aptitude with a material to be used.

It is necessary that the gate insulating film 20 has a thickness to decrease a leakage current and to improve voltage resistance. On the other hand, when the thickness of the gate insulating film 20 is excessively large, the drive voltage increases. Although depending on the material, the thickness of the gate insulating film 20 is preferably 10 nm to 10 μm, more preferably 50 nm to 1000 nm, and still more preferably 100 nm to 400 nm.

(Gate Electrode)

After the formation of the gate insulating film 20, the gate electrode 22 is formed. The gate electrode 22 can be formed of a highly conductive material, and examples of the material include metal such as Al, Mo, Cr, Ta, Ti, Au, or Au, Al—Nd, a Ag alloy, and a metal oxide conductive film such as tin oxide, zinc oxide, indium oxide, indium tin oxide (ITO), indium zinc oxide (IZO) or IGZO. The gate electrode 22 may have a single-layer structure or a laminate structure including two or more layers of the above conductive films.

The gate electrode 22 is formed using a method which is appropriately selected from a wet method such as a printing method or coating method, a physical method such as a vacuum deposition method, a sputtering method, or an ion plating method, and a chemical method such as a CVD method or a plasma CVD method in consideration of aptitude with a material to be used.

In consideration of film formability, patterning characteristics using an etching or lift-off method, conductivity, and the like, the thickness of the metal film for forming the gate electrode 22 is preferably 10 nm to 1000 nm and more preferably 50 nm to 200 nm.

The gate electrode 22 may be formed, for example, by forming a film and then patterning the film into a predetermined shape using an etching or lift-off method or by directly forming a pattern using an ink jet method or the like. At this time, it is preferable that the gate electrode 22 and gate wirings (not shown) are simultaneously patterned.

The use of the above-described thin film transistor 10 according to the embodiment is not particularly limited. However, the thin film transistor 10 exhibits strong transport characteristics and thus is suitably used as a drive element in a display apparatus such as a liquid crystal display apparatus, an organic electroluminescence (EL) display apparatus, or an inorganic EL display apparatus. In particular, the thin film transistor 10 is particularly suitable for manufacturing a flexible display using a resin substrate having low heat resistance.

Further, the thin film transistor which is manufactured according to the present invention is preferably used as a drive element (drive circuit) in various electronic devices including various sensors such as an X-ray sensor or an image sensor and a micro electromechanical system (MEMS).

<Liquid Crystal Display Apparatus>

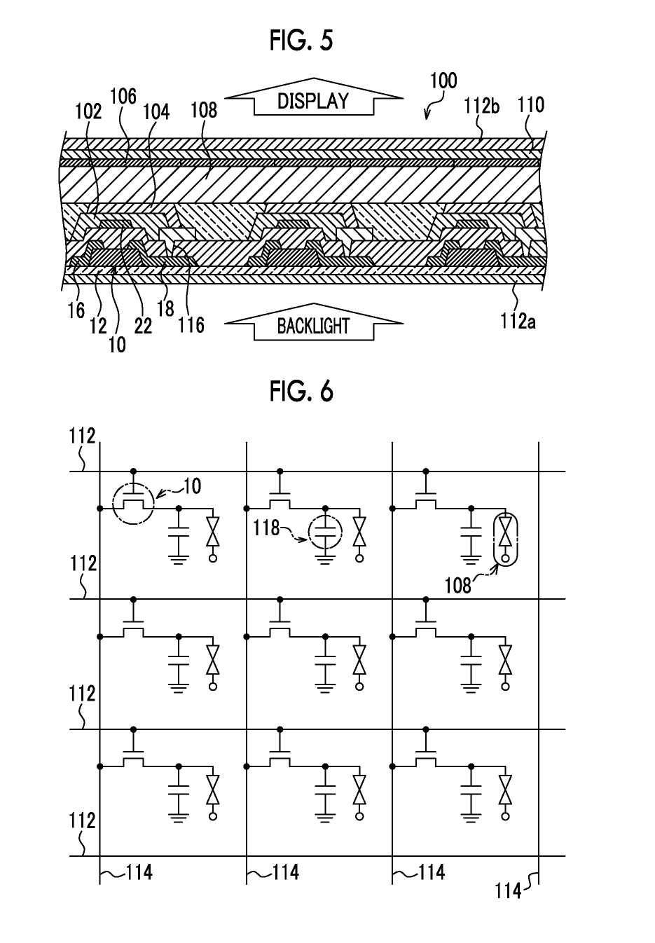

Regarding a liquid crystal display apparatus according to an embodiment of the present invention, FIG. 5 is a schematic cross-sectional view showing a part thereof, and FIG. 6 is a schematic diagram showing a configuration of electric wirings thereof

As shown in FIG. 5, a liquid crystal display apparatus 100 according to the embodiment includes: the top contact type TFT 10 having a top gate structure shown in FIG. 1; a liquid crystal layer 108 that is formed on the gate electrode 22, protected by a passivation layer 102 of the TFT 10, to be interposed between a pixel lower electrode 104 and an opposite upper electrode 106; and a RGB (red, green, blue) color filter 110 that exhibits different colors according to each pixel. In addition, polarizing plates 112a and 112b are provided on the substrate 12 side and the RGB color filter 110 of the TFT 10.

In addition, as shown in FIG. 6, the liquid crystal display apparatus 100 according to the embodiment includes: plural gate wirings 112 that are parallel to each other; and plural data wirings 114 that intersect with the gate wirings 112 and are parallel to each other. Here, the gate wirings 112 and the data wirings 114 are electrically insulated from each other. The TFT 10 is provided near intersections between the gate wirings 112 and the data wirings 114.

The gate electrode 22 of the TFT 10 is connected to the gate wirings 112, and the source electrode 16 of the TFT 10 is connected to the data wirings 114. In addition, the drain electrode 18 of the TFT 10 is connected to the pixel lower electrode 104 through a contact hole 116 (a conductor is embedded in the contact hole 116) provided in the gate insulating film 20. The pixel lower electrode 104 forms a capacitor 118 with the opposite upper electrode 106 which is grounded.

<Organic EL Display Apparatus>

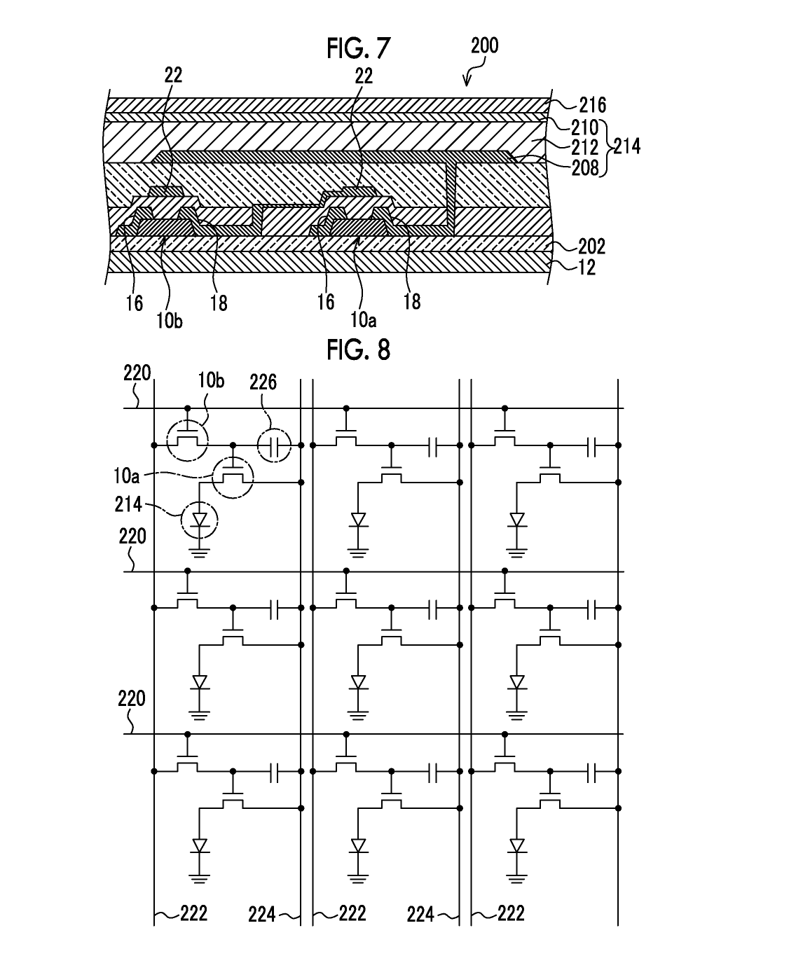

Regarding an active matrix organic EL display apparatus according to an embodiment of the present invention, FIG. 7 is a schematic cross-sectional view showing a part thereof, and FIG. 8 is a schematic diagram showing a configuration of electric wirings thereof.

In an active matrix organic EL display apparatus 200 according to the embodiment, the TFTs 10 having a top gate structure shown in FIG. 1 are provided on the substrate 12 including a passivation layer 202 as a driving TFT 10a and a switching TFT 10b, an organic EL light emitting element 214 that includes an organic light emitting layer 212 interposed between a lower electrode 208 and an upper electrode 210 is provided on the TFTs 10a and 10b, and a top surface of the organic EL light emitting element 214 is protected by a passivation layer 216.

In addition, as shown in FIG. 8, the organic EL display apparatus 200 according to the embodiment includes: plural gate wirings 220 that are parallel to each other; and plural data wirings 222 and driver wirings 224 that intersect with the gate wirings 220 and are parallel to each other. Here, the gate wirings 220, the data wirings 222, and the driver wirings 224 are electrically insulated from each other. The gate electrode 22 of the switching TFT 10b is connected to the gate wirings 220, and the source electrode 16 of the switching TFT 10b is connected to the data wirings 222. In addition, the drain electrode 18 of the switching TFT 10b is connected to the gate electrode 22 of the driving TFT 10a, and the on-state of the driving TFT 10a is maintained by using a capacitor 226. The source electrode 16 of the driving TFT 10a is connected to the driver wirings 224, and the drain electrode 18 is connected to the organic EL light emitting element 214.

The organic EL display apparatus shown in FIG. 7 may be a top emission type by using a transparent electrode as the upper electrode 210 or may be a bottom emission type by using a transparent electrode as the lower electrode 208 and each electrode of the TFT.

<X-Ray Sensor>

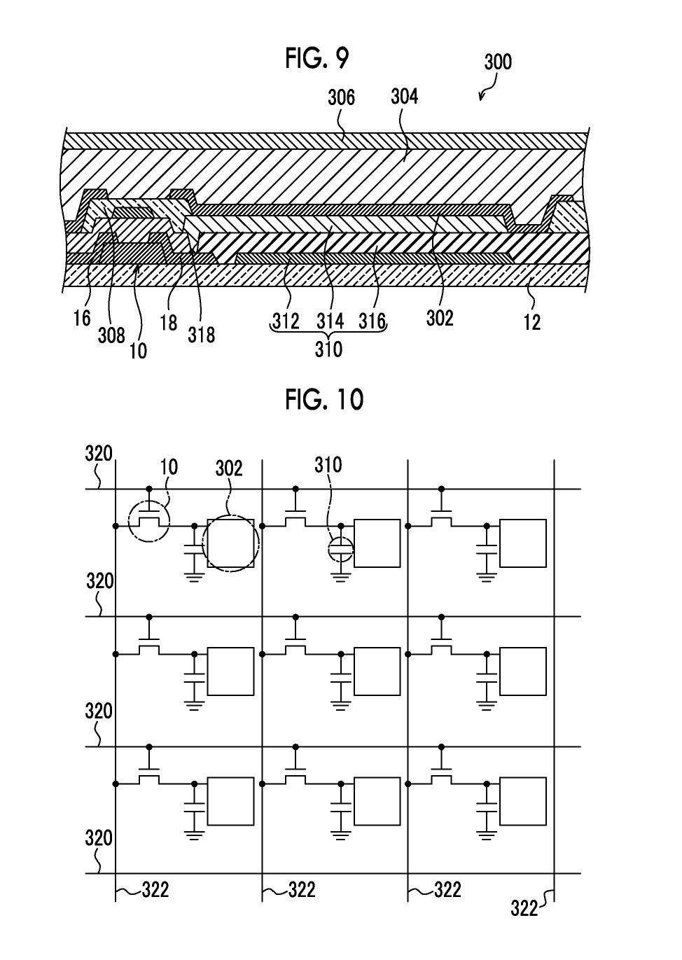

Regarding an X-ray sensor according to an embodiment of the present invention, FIG. 9 is a schematic cross-sectional view showing a part thereof, and FIG. 10 is a schematic diagram showing a configuration of electric wirings thereof.

An X-ray sensor 300 according to the embodiment includes: the TFT 10 and a capacitor 310 that are formed on the substrate 12; a charge collection electrode 302 that is formed on the capacitor 310; an X-ray conversion layer 304; and an upper electrode 306. A passivation film 308 is provided on the TFT 10.

The capacitor 310 has a structure in which an insulating film 316 is interposed between a lower electrode 312 for a capacitor and an upper electrode 314 for a capacitor. The upper electrode 314 for a capacitor is connected to any one (in FIG. 9, the drain electrode 18) of the source electrode 16 and the drain electrode 18 of the TFT 10 through a contact hole 318 provided in the insulating film 316.

The charge collection electrode 302 is provided on the upper electrode 314 for a capacitor in the capacitor 310 and is connected to the upper electrode 314 for a capacitor.

The X-ray conversion layer 304 is formed of amorphous selenium and is provided to cover the TFT 10 and the capacitor 310.

The upper electrode 306 is provided on the X-ray conversion layer 304 and contacts the X-ray conversion layer 304.

As shown in FIG. 10, the X-ray sensor 300 according to the embodiment includes: plural gate wirings 320 that are parallel to each other; and plural data wirings 322 that intersect with the gate wirings 320 and are parallel to each other. Here, the gate wirings 320 and the data wirings 322 are electrically insulated from each other. The TFT 10 is provided near intersections between the gate wirings 320 and the data wirings 322.

The gate electrode 22 of the TFT 10 is connected to the gate wirings 320, and the source electrode 16 of the TFT 10 is connected to the data wirings 322. In addition, the drain electrode 18 of the TFT 10 is connected to the charge collection electrode 302, and the charge collection electrode 302 is connected to the capacitor 310.

In the X-ray sensor 300 according to the embodiment, in FIG. 9, X-rays are incident from the upper electrode 306 side to generate electron-hole pairs on the X-ray conversion layer 304. When a high electric field is applied to the X-ray conversion layer 304 by the upper electrode 306, the generated charges accumulate on the capacitor 310 and are read by sequentially scanning the TFT 10.

In the liquid crystal display apparatus 100, the organic EL display apparatus 200, and the X-ray sensor 300 according to the embodiments, the TFT having a top gate structure is provided. However, the TFT is not limited to this configuration and may have a structure shown in each of FIGS. 2 to 4.

### EXAMPLES

Hereinafter, Examples of the present invention will be described, but the present invention is not limited to these Examples.

### Example 1 and Comparative Example 1

The following device for evaluation was prepared and was evaluated.

Indium nitrate (In(NO₃)₃.xH₂O, 4 N, manufactured by Kojundo Chemical Laboratory Co., Ltd.) was dissolved in 2-methoxyethanol (special grade chemical, manufactured by Wako Pure Chemical Industries, Ltd.). In this way, indium nitrate solutions having different indium nitrate concentrations as shown in Table 1 below were prepared.

TABLE 1

| | Indium Nitrate Concentration |
|---|---|
| | (mol/L) |
| Solution A | 0.1 |
| Solution B | 0.01 |

A simple TFT was prepared in which a p-type Si substrate with a thermal oxide film (thickness: 100 nm) was used as a substrate, and the thermal oxide film was used as a gate insulating film.

The p-type Si substrate with the thermal oxide film having a size of 1 inch×1 inch was spin-coated with each of the prepared solutions at a rotating speed of 1500 rpm for 30 seconds. Next, the coating solution was dried on a hot plate heated to 60° C. for 1 minute. As a result, a metal oxide semiconductor precursor film was obtained.

A heat treatment was performed on the obtained metal oxide semiconductor precursor film by irradiating the metal oxide semiconductor precursor film with ultraviolet rays under the following conditions. As a result, the metal oxide semiconductor precursor film was converted into a metal oxide semiconductor film.

As an ultraviolet irradiation device, a UV ozone cleaner (UV253H, manufactured by Filgen, Inc.) using a low pressure mercury lamp was used. A sample was set on a 40 mm glass plate, and the distance between the lamp and the sample was 5 mm. The illuminance of ultraviolet rays having a wavelength of 254 nm at a sample position was measured using a ultraviolet light meter (UV-M10, manufactured by Orc Manufacturing Co., Ltd.; light receiving unit UV-25). A lighting lamp reached a maximum value of 15 mW/cm² for 3 minutes.

In a ultraviolet irradiation chamber, nitrogen was caused to flow at 6 L/min for 10 minutes and ultraviolet irradiation was performed for 90 minutes. In the ultraviolet irradiation, nitrogen was caused to flow, typically, at 6 L/min. During the ultraviolet irradiation, the substrate temperature was 160° C. when monitored by THERMO LABEL.

Regarding the substrate coated with Solution A, the coating and drying of the solution and the conversion of the metal oxide semiconductor precursor film into a metal oxide semiconductor film through the ultraviolet irradiation were performed once (Comparative Example 1).

Regarding the substrate coated with Solution B, the coating and drying of the solution and the conversion of the metal oxide semiconductor precursor film into a metal oxide semiconductor film through the ultraviolet irradiation were alternately repeated 12 times (Example 1).

The thicknesses of the metal oxide semiconductor films of Example 1 and Comparative Example 1 were within a range of 10.5 nm±1.0 nm when sections thereof were observed with a TEM. Therefore, it was found that there is no significant difference between the thicknesses of the samples. In addition, in all the samples, a clear interface layer was not observed in the film.

Source-drain electrodes were formed by vapor deposition on the obtained metal oxide semiconductor film. Patterns of the source-drain electrodes were formed using a metal mask, and a Ti film having a thickness of 50 nm was formed. The size of each of the source-drain electrodes was 1 mm×1 mm, and the distance between the electrodes was 0.2 mm.

Regarding the obtained simple TFT, transistor characteristics (V_{g}-I_{d} characteristics) were measured using a semiconductor parameter analyzer 4156C (manufactured by Agilent Technologies Inc.).

During the measurement of V_{g}-I_{d} characteristics, the drain voltage (V_{d}) was fixed to +1 V, the gate voltage (V_{g}) was changed in a range of −15 V to +15 V, and the drain current (I_{d}) at each gate voltage (V_{g}) was measured.

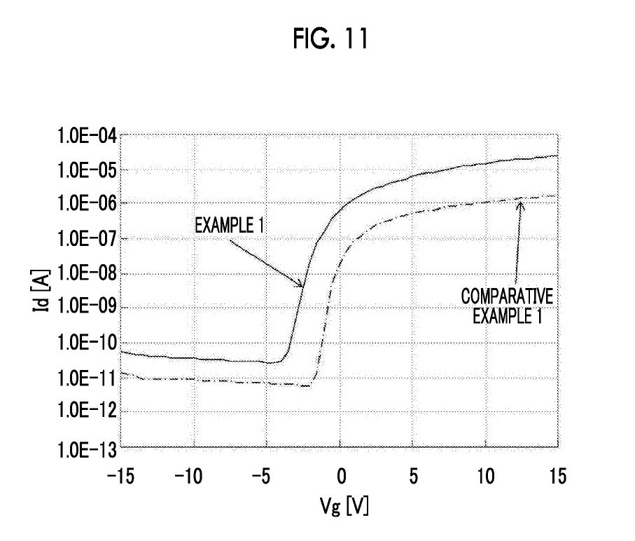

FIG. 11 shows V_{g}-I_{d} characteristics of Example 1 and Comparative Example 1, respectively. In addition, Table 2 shows linear mobility (hereinafter, also referred to as “mobility”) values of Example 1 and Comparative Example 1 estimated from V_{g}-I_{d} characteristics.

TABLE 2

| | Linear Mobility |
|---|---|
| | (cm²/Vs) |
| Comparative Example 1 | 0.5 |
| Example 1 | 8.9 |

### Examples 2, 3 and Comparative Examples 2, 3, 4

The following device for evaluation was prepared and was evaluated.

A simple TFT was prepared in which a p-type Si substrate with a thermal oxide film (thickness: 100 nm) was used as a substrate, and the thermal oxide film was used as a gate insulating film.

### Example 2

### The Coating and the Hot Plate Heating were Repeated 12 Times

The p-type Si substrate with the thermal oxide film having a size of 1 inch×1 inch was spin-coated with Solution B at a rotating speed of 1500 rpm for 30 seconds. Next, the coating solution was dried on a hot plate heated to 60° C. for 1 minute. As a result, a metal oxide semiconductor precursor film was obtained.

A heat treatment was performed on the obtained metal oxide semiconductor precursor film by heating the metal oxide semiconductor precursor film with a hot plate under the following conditions. As a result, the metal oxide semiconductor precursor film was converted into a metal oxide semiconductor film.

The metal oxide semiconductor precursor film was placed on the hot plate heated to 250° C., and a heat treatment was performed thereon for 5 minutes.

The coating and drying of the solution and the conversion of the metal oxide semiconductor precursor film into a metal oxide semiconductor film through the heat treatment with the hot plate were alternately repeated 12 times. A heat treatment was performed again on the obtained metal oxide semiconductor film in air using the hot plate heated to 250° C. for 90 minutes.

### Example 3

### UV Annealing after the Coating and the Hot Plate Heating were Repeated 12 Times

The p-type Si substrate with the thermal oxide film having a size of 1 inch×1 inch was spin-coated with Solution B at a rotating speed of 1500 rpm for 30 seconds. Next, the coating solution was dried on a hot plate heated to 60° C. for 1 minute. As a result, a metal oxide semiconductor precursor film was obtained.

A heat treatment was performed on the obtained metal oxide semiconductor precursor film by heating the metal oxide semiconductor precursor film with a hot plate under the following conditions. As a result, the metal oxide semiconductor precursor film was converted into a metal oxide semiconductor film.

The metal oxide semiconductor precursor film was placed on the hot plate heated to 250° C., and a heat treatment was performed thereon for 5 minutes.

The coating and drying of the solution and the conversion of the metal oxide semiconductor precursor film into a metal oxide semiconductor film through the heat treatment with the hot plate were alternately repeated 12 times. A heat treatment was performed on the obtained metal oxide semiconductor precursor film by irradiating the metal oxide semiconductor precursor film with ultraviolet rays under the following conditions.

As an ultraviolet irradiation device, a UV ozone cleaner (UV253H, manufactured by Filgen, Inc.) using a low pressure mercury lamp was used. A sample was set on a 40 mm glass plate, and the distance between the lamp and the sample was 5 mm. The illuminance of ultraviolet rays having a wavelength of 254 nm at a sample position was measured using a ultraviolet light meter (UV-M10, manufactured by Orc Manufacturing Co., Ltd.; light receiving unit UV-25). A lighting lamp reached a maximum value of 15 mW/cm² for 3 minutes.

In a ultraviolet irradiation chamber, nitrogen was caused to flow at 6 L/min for 10 minutes and ultraviolet irradiation was performed for 90 minutes. In the ultraviolet irradiation, nitrogen was caused to flow, typically, at 6 L/min. During the ultraviolet irradiation, the substrate temperature was 160° C. when monitored by THERMO LABEL.

### Comparative Example 2

### The Coating and the Hot Plate Heating at 160° C. were Performed Once

The p-type Si substrate with the thermal oxide film having a size of 1 inch×1 inch was spin-coated with Solution A at a rotating speed of 1500 rpm for 30 seconds. Next, the coating solution was dried on a hot plate heated to 60° C. for 1 minute. As a result, a metal oxide semiconductor precursor film was obtained.

A heat treatment was performed on the obtained metal oxide semiconductor precursor film by heating the metal oxide semiconductor precursor film with a hot plate under the following conditions. As a result, the metal oxide semiconductor precursor film was converted into a metal oxide semiconductor film.

The metal oxide semiconductor precursor film was placed on the hot plate heated to 160° C., and a heat treatment was performed thereon for 90 minutes.

### Comparative Example 3

### The Coating and the Hot Plate Heating at 250° C. were Performed Once

The p-type Si substrate with the thermal oxide film having a size of 1 inch×1 inch was spin-coated with Solution A at a rotating speed of 1500 rpm for 30 seconds. Next, the coating solution was dried on a hot plate heated to 60° C. for 1 minute. As a result, a metal oxide semiconductor precursor film was obtained.

A heat treatment was performed on the obtained metal oxide semiconductor precursor film by heating the metal oxide semiconductor precursor film with a hot plate under the following conditions. As a result, the metal oxide semiconductor precursor film was converted into a metal oxide semiconductor film.

The metal oxide semiconductor precursor film was placed on the hot plate heated to 250° C., and a heat treatment was performed thereon for 90 minutes.

### Comparative Example 4

### UV Annealing after the Coating and the Hot Plate Heating at 160° C. were Repeated 12 Times

The p-type Si substrate with the thermal oxide film having a size of 1 inch×1 inch was spin-coated with Solution B at a rotating speed of 1500 rpm for 30 seconds. Next, the coating solution was dried on a hot plate heated to 60° C. for 1 minute. As a result, a metal oxide semiconductor precursor film was obtained.

A heat treatment was performed on the obtained metal oxide semiconductor precursor film using a hot plate under the following conditions.

The metal oxide semiconductor precursor film was placed on the hot plate heated to 160° C., and a heat treatment was performed thereon for 5 minutes.

The coating and drying of the solution and the heat treatment using the hot plate were alternately repeated 12 times. A heat treatment was performed on the obtained metal oxide semiconductor precursor film by irradiating the metal oxide semiconductor precursor film with ultraviolet rays under the following conditions.

As an ultraviolet irradiation device, a UV ozone cleaner (UV253H, manufactured by Filgen, Inc.) using a low pressure mercury lamp was used. A sample was set on a 40 mm glass plate, and the distance between the lamp and the sample was 5 mm. The illuminance of ultraviolet rays having a wavelength of 254 nm at a sample position was measured using a ultraviolet light meter (UV-M10, manufactured by Orc Manufacturing Co., Ltd.; light receiving unit UV-25). A lighting lamp reached a maximum value of 15 mW/cm² for 3 minutes.

In a ultraviolet irradiation chamber, nitrogen was caused to flow at 6 L/min for 10 minutes and ultraviolet irradiation was performed for 90 minutes. In the ultraviolet irradiation, nitrogen was caused to flow, typically, at 6 L/min. During the ultraviolet irradiation, the substrate temperature was 160° C. when monitored by THERMO LABEL.

Source-drain electrodes were formed by vapor deposition on the obtained metal oxide semiconductor film using the same method as in Example 1, and V_{g}-I_{d} characteristics were measured using the same method as in Example 1.

Table 3 shows linear mobility estimated from V_{g}-I_{d} characteristics in Examples 2 and 3 and Comparative Example 2, 3, and 4.

TABLE 3

| | Linear Mobility |
|---|---|
| | (cm²/Vs) |
| Example 2 | 7.4 |
| Example 3 | 7.5 |
| Comparative | Not Operated |
| Example 2 | |
| Comparative | 0.5 |
| Example 3 | |
| Comparative | 0.5 |
| Example 4 | |

[SIMS Analysis]

The metal oxide semiconductor films of Examples 1, 2, and 3 and Comparative Examples 1, 2, 3, and 4 were analyzed by SIMS. A measuring device was PHI ADEPT 1010 manufactured by ULVAC PHI Inc., and measurement conditions were primary ion species: Cs⁺, primary acceleration voltage: 1.0 kV, and detection region: 140 μm×140 μm.

Table 4 below shows the nitrogen concentration, hydrogen concentration, and carbon concentration of Examples 1, 2, and 3 and Comparative Examples 1, 2, 3, and 4 which were estimated from the SIMS analysis.

TABLE 4

| | Hydrogen | Nitrogen | Carbon |
|---|---|---|---|
| | Concentration | Concentration | Concentration |
| | (atoms/cm³) | (atoms/cm³) | (atoms/cm³) |
| Example 1 | 3.0 × 10²² | 1.1 × 10²⁰ | 4.0 × 10²⁰ |
| Example 2 | 1.2 × 10²² | 1.7 × 10²⁰ | 8.6 × 10²⁰ |
| Example 3 | 2.1 × 10²² | 2.7 × 10²⁰ | 9.0 × 10²⁰ |
| Comparative | 4.9 × 10²² | 2.6 × 10²⁰ | 6.0 × 10¹⁹ |
| Example 1 | | | |
| Comparative | 3.6 × 10²² | 9.0 × 10²⁰ | 7.0 × 10²¹ |
| Example 2 | | | |
| Comparative | 4.5 × 10²² | 1.2 × 10¹⁹ | 3.2 × 10²¹ |
| Example 3 | | | |
| Comparative | 6.0 × 10²² | 1.3 × 10²⁰ | 3.8 × 10²⁰ |
| Example 4 | | | |

[RBS Analysis]

The metal oxide semiconductor films of Examples 1, 2, and 3 and Comparative Examples 1, 2, 3, and 4 were analyzed by Rutherford backscattering spectroscopy (RBS). A measuring device was RBS manufactured by CE&A Co., Ltd., and measurement conditions were incident ion species: 2.275 MeV 4 He++, beam diameter: 1 mmφ to 2 mmφ, and RBS detection angle: normal angle 160° and grazing angle 94.5°.

Next, the metal oxide semiconductor films of Examples 1, 2, and 3 and Comparative Examples 1, 2, 3, and 4 were analyzed by XRR. A measuring device was ATX-G manufactured by Rigaku Corporation, and measurement conditions were scanning rate: 0.2°/min, and step width: 0.001°. In the obtained XRR spectrum, a range of 0.3° to 4.0° was set as an analysis range, and conditions were primary ion species: Cs⁺, primary acceleration voltage: 1.0 kV, and detection region: 140 μm×140 μm.

Table 5 shows the indium concentrations of Examples 1, 2, and 3 and Comparative Examples 1, 2, 3, and 4, which were estimated from the surface density obtained by RBS analysis and the film density obtained by XRR, and the film densities of Examples 1, 2, and 3 and Comparative Examples 1, 2, 3, and 4 which were estimated by XRR analysis.

TABLE 5

| | Indium Concentration | Film Density |
|---|---|---|
| | (atoms/cm³) | (g/cm³) |
| Example 1 | 2.36 × 10²² | 6.28 |
| Example 2 | 2.33 × 10²² | 6.84 |
| Example 3 | 2.33 × 10²² | 6.19 |
| Comparative Example 1 | 2.18 × 10²² | 5.80 |
| Comparative Example 2 | 1.57 × 10²² | 4.17 |
| Comparative Example 3 | 1.77 × 10²² | 4.71 |
| Comparative Example 4 | 1.94 × 10²² | 5.16 |

Table 6 below shows a ratio (D_{H}/D_{J}) of the hydrogen concentration D_{H} (atoms/cm³) to the indium concentration D_{I} (atoms/cm³) in the film estimated from Tables 4 and 5, a ratio (D_{N}/D_{J}) of the nitrogen concentration D_{N} (atoms/cm³) to the indium concentration D_{I} (atoms/cm³), and a ratio (D_{C}/D_{I}) of the carbon concentration D_{C} (atoms/cm³) to the indium concentration D_{I} (atoms/cm³).

TABLE 6

| | | | | Linear Mobility |
|---|---|---|---|---|
| | D_{H}/D_{I} | D_{N}/D_{I} | D_{C}/D_{I} | (cm²/Vs) |
| Example 1 | 1.27 | 4.66 × 10⁻³ | 1.69 × 10⁻² | 8.9 |
| Example 2 | 0.51 | 7.29 × 10⁻³ | 3.69 × 10⁻² | 7.4 |
| Example 3 | 0.90 | 1.16 × 10⁻² | 3.86 × 10⁻² | 7.5 |
| Comparative | 2.25 | 1.19 × 10⁻² | 2.52 × 10⁻³ | 0.5 |
| Example 1 | | | | |
| Comparative | 2.29 | 5.74 × 10⁻² | 4.46 × 10⁻¹ | Not Operated |
| Example 2 | | | | |
| Comparative | 2.54 | 6.77 × 10⁻² | 1.81 × 10⁻¹ | 0.5 |
| Example 3 | | | | |
| Comparative | 3.09 | 6.70 × 10⁻³ | 1.96 × 10⁻² | 0.5 |
| Example 4 | | | | |

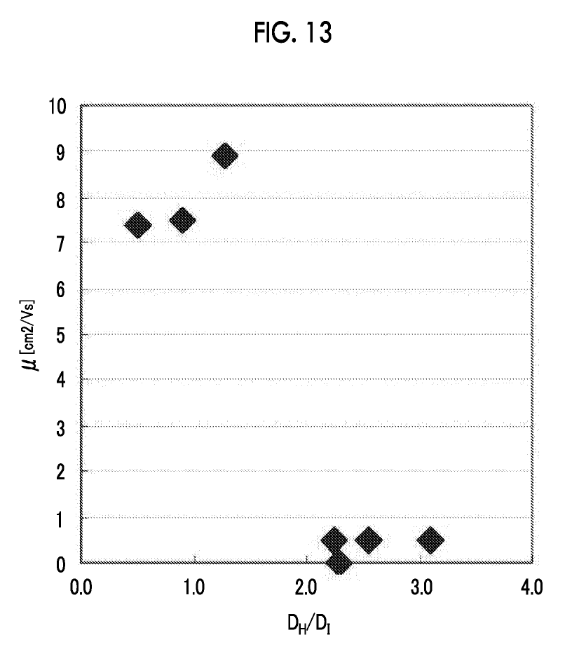

FIG. 13 shows a relationship between D_{H}/D_{J} and mobility. When DH/DI≦1.8, a high mobility value of 5 cm²/Vs or higher is obtained from an extrapolated line between a point exhibiting high mobility and a point exhibiting low mobility.

The disclosure of Japanese Patent Application No. 2013-253191 is incorporated herein in its entirety.

All publications, patent applications, and technical standards mentioned in this specification are herein incorporated by reference to the same extent as if each individual publication, patent application, or technical standard was specifically and individually indicated to be incorporated by reference.

What is claimed is:

1. A metal oxide semiconductor film comprising at least indium as a metal component,
wherein when an indium concentration in the metal oxide semiconductor film is represented by D_{I} (atoms/cm³), and when a hydrogen concentration in the metal oxide semiconductor film is represented by D_{H} (atoms/cm³), the following relational expression (1) is satisfied:
0.1≦D_{H}/D_{I}≦1.8 (1).

2. The metal oxide semiconductor film according to claim 1,
wherein the following relational expression (2) is satisfied:
0.5≦D_{H}/D_{I}≦1.3 (2).

3. The metal oxide semiconductor film according to claim 1,
wherein an indium content in the metal oxide semiconductor film is 50 atom % or higher with respect to all the metal elements included in the metal oxide semiconductor film.

4. The metal oxide semiconductor film according to claim 1,
wherein an average film density is 6 g/cm³ or higher when measured by X-ray reflectometry.

5. The metal oxide semiconductor film according to claim 1,
wherein when a nitrogen concentration in the metal oxide semiconductor film is represented by D_{N} (atoms/cm³), the following relational expression (3) is satisfied:
0.004≦D_{N}/D_{I}≦0.012 (3).

6. The metal oxide semiconductor film according to claim 1,
wherein when a carbon concentration in the metal oxide semiconductor film is represented by D_{C} (atoms/cm³), the following relational expression (4) is satisfied:
0.016≦D_{C}/D_{I}≦0.039 (4).

7. The metal oxide semiconductor film according to claim 1,
wherein not only indium but also at least one metal element selected from the group consisting of zinc, tin, gallium, and aluminum are included as metal components.

8. A thin film transistor comprising:
an active layer that includes the metal oxide semiconductor film according to claim 1;
a source electrode;
a drain electrode;
a gate insulating film; and
a gate electrode.

9. A display apparatus comprising
the thin film transistor according to claim 8.

10. An image sensor comprising
the thin film transistor according to claim 8.

11. An X-ray sensor comprising
the thin film transistor according to claim 8.
